(19) United States
(12) Patent Application Publication
(10) Pub. No.: US 2023/0238860 A1
(43) Pub. Date: Jul. 27, 2023

(54) ROTATION ANGLE DETECTION DEVICE AND ROTARY ELECTRIC MACHINE USING SAME

(71) Applicant: Mitsubishi Electric Corporation, Tokyo (JP)

(72) Inventors: Tatsuya KITAMURA, Tokyo (JP); Yosuke UNO, Tokyo (JP)

(73) Assignee: Mitsubishi Electric Corporation, Tokyo (JP)

(21) Appl. No.: 17/871,299

(22) Filed: Jul. 22, 2022

(30) Foreign Application Priority Data
Jan. 27, 2022 (JP) 2022-010685

(51) Int. Cl. H02K 11/215; H02K 11/01; H02K 1/16

(52) U.S. Cl. CPC H02K 11/215; H02K 1/16; H02K 11/0141; G01R 33/07

(57) ABSTRACT

The rotation angle detection device includes: a magnet; a magnetic detection element disposed on the one side in the axial direction relative to the magnet with a gap interposed between the magnetic detection element and the magnet; and a shield. The shield is disposed at a location in the axial direction between a location in the axial direction of a wire member allowing current to flow therethrough and a location in the axial direction of the magnetic detection element, is disposed radially outward of the magnet as seen in the axial direction, and has a portion that overlaps with the wire member as seen in the axial direction. The wire member is disposed at a location in the axial direction that is closer to the magnet than the magnetic detection element is, and is disposed radially outward of the magnet as seen in the axial direction.

### BACKGROUND OF THE INVENTION

### 1. Field of the Invention

The present disclosure relates to a rotation angle detection device and a rotary electric machine using the same.

### 2. Description of the Background Art

Demand for enhancing fuel efficiency of automobiles has been intensified in recent years in view of global warming. Along with the demand, the prices of automobile parts have been required to be reduced for extensively spreading automobiles throughout broad regions and among people. The need for employing constituents that have reduced sizes and reduced weights and that are highly economical, has been intensified also for field-winding-type power generators that charge on-board batteries and that supply power to be consumed by vehicle electrical parts. Meanwhile, the number of electrical parts per automobile and power consumed per automobile tend to increase, and power generators for vehicles are required to have power generation performance and drive performance so as to generate a larger amount of power and so as to be more efficient. In addition, control device-integrated rotary electric machines in which a control device having a power conversion function and a sensing function is integrated with a motor so that an engine assist function or a start-stop function is realized, have been developed for further improving efficiency.

Each control device-integrated rotary electric machine includes a sensor for detecting a rotation speed and a rotation angle of a rotor. Examples of a detection method employed by the sensor for detecting the rotation speed and the rotation angle include a resolver method and a magnetic method. In the magnetic method, a magnetic detection element and a magnet are used in combination. The magnetic detection element ascertains a change in a magnetic flux due to the magnet rotating integrally with a shaft of the rotary electric machine, to detect the rotation speed and the rotation angle of the rotor.

The magnetic detection element detects signal magnetic flux which is a magnetic flux having flowed out from the magnet, to detect the rotation speed and the rotation angle of the rotor. Therefore, if there is disturbance magnetic flux which is a magnetic flux other than signal magnetic flux from the magnet, a speed error or an angle error is added to an output from the magnetic detection element. The accuracy of rotation angle detection by the sensor directly influences power generation efficiency or drive efficiency of the rotary electric machine. Thus, if the accuracy of rotation angle detection by the sensor is reduced, the power generation efficiency or the drive efficiency of the rotary electric machine is significantly reduced. Against such a problem, a structure of a rotation angle sensor including a magnetic shield for reducing disturbance magnetic fluxes so that the accuracies of rotation speed detection and rotation angle detection are kept high, has been disclosed (see, for example, Patent Document 1).

The disclosed rotation angle sensor includes: a shaft formed from a non-magnetic material; and a magnetic shield case which is formed from a ferromagnetic material so as to have the shape of a container with a bottom and in which an insertion hole having a larger diameter than the shaft is formed in the bottom. In the rotation angle sensor, a magnet and the shaft are inserted in the insertion hole of the magnetic shield case with a predetermined gap, and the magnet and a magnetic detection element are disposed so as to be accommodated in the magnetic shield case. Since the rotation angle sensor has the magnet and the magnetic detection element accommodated in the magnetic shield case, influence of disturbance magnetic flux is suppressed. Thus, reduction of the accuracies of rotation speed detection and rotation angle detection can be prevented.

Patent Document 1: Japanese Patent No. 3086563

In the above Patent Document 1, the magnetic shield case formed from a ferromagnetic material is provided, and thus influence of disturbance magnetic flux is suppressed, whereby reduction of the accuracies of rotation speed detection and rotation angle detection can be prevented. However, since the magnet and the magnetic detection element are accommodated in the magnetic shield case having a low magnetic resistance, signal magnetic fluxes from the magnet are guided to the magnetic shield case around the magnet. Consequently, a problem arises in that signal magnetic fluxes that enter the magnetic detection element in a magnetic detection direction thereof are likely to be reduced. In addition, if the signal magnetic fluxes that enter the magnetic detection element in the magnetic detection direction thereof are reduced, a problem arises in that the accuracies of rotation speed detection and rotation angle detection are reduced.

### SUMMARY OF THE INVENTION

Considering this, an object of the present disclosure is to: provide a rotation angle detection device in which reduction of signal magnetic fluxes that enter a magnetic detection element in a magnetic detection direction thereof, and influence of disturbance magnetic fluxes that enter the magnetic detection element in the magnetic detection direction thereof, are suppressed so that reduction of the accuracies of rotation speed detection and rotation angle detection is prevented; and provide a highly-efficient rotary electric machine by preventing reduction of the accuracies of rotation speed detection and rotation angle detection which are performed by the rotation angle detection device.

A rotation angle detection device according to the present disclosure includes: a magnet provided on one side in an axial direction of a shaft and configured to rotate integrally with the shaft; a magnetic detection element disposed on the one side in the axial direction relative to the magnet with a gap interposed between the magnetic detection element and the magnet; and a shield formed from a magnetic material. The shield is disposed at a location in the axial direction between a location in the axial direction of a wire member allowing current to flow therethrough and a location in the axial direction of the magnetic detection element, is disposed radially outward of the magnet as seen in the axial direction, and has a portion that overlaps with the wire member as seen in the axial direction. The wire member is disposed at a location in the axial direction that is closer to the magnet than the magnetic detection element is, and disposed radially outward of the magnet as seen in the axial direction.

A rotary electric machine according to the present disclosure includes: the rotation angle detection device according to the present disclosure; the shaft; the wire member; a rotor configured to rotate integrally with the shaft and having a field winding and a field core around which the field winding is wound; a stator disposed radially outward of the rotor and having a stator core around which an armature winding is wound; and a bracket covering an outer side of each of the rotor and the stator and holding one end side and another end side of the shaft via bearings.

The rotation angle detection device according to the present disclosure includes: a magnet configured to rotate integrally with a shaft; a magnetic detection element disposed with a gap interposed between the magnetic detection element and the magnet; and a shield formed from a magnetic material. The shield is disposed at a location in the axial direction between a location in the axial direction of a wire member allowing current to flow therethrough and a location in the axial direction of the magnetic detection element, is disposed radially outward of the magnet as seen in the axial direction, and has a portion that overlaps with the wire member as seen in the axial direction. The wire member is disposed at a location in the axial direction that is closer to the magnet than the magnetic detection element is, and is disposed radially outward of the magnet as seen in the axial direction. Consequently, disturbance magnetic fluxes generated around the wire member are guided to the shield, and disturbance magnetic fluxes that enter the magnetic detection element are reduced. Therefore, influence of the disturbance magnetic fluxes that enter the magnetic detection element in a magnetic detection direction thereof is suppressed, whereby reduction of the accuracies of rotation speed detection and rotation angle detection can be prevented. In addition, the shield is disposed radially outward of the magnet as seen in the axial direction, and guidance, to the shield, of signal magnetic fluxes generated from the magnet is suppressed. Consequently, reduction of signal magnetic fluxes that enter the magnetic detection element in the magnetic detection direction thereof is suppressed, whereby reduction of the accuracies of rotation speed detection and rotation angle detection can be prevented.

The rotary electric machine according to the present disclosure includes: the rotation angle detection device according to the present disclosure; the shaft; the wire member; a rotor configured to rotate integrally with the shaft and having a field winding and a field core around which the field winding is wound; a stator disposed radially outward of the rotor and having a stator core around which an armature winding is wound; and a bracket covering an outer side of each of the rotor and the stator and holding one end side and another end side of the shaft via bearings. Consequently, disturbance magnetic fluxes generated around the wire member are guided to the shield so that influence of disturbance magnetic fluxes that enter the magnetic detection element in the magnetic detection direction thereof is suppressed. Furthermore, guidance, to the shield, of signal magnetic fluxes generated from the magnet is suppressed. Therefore, reduction of the accuracies of rotation speed detection and rotation angle detection is prevented, whereby a highly-efficient rotary electric machine can be obtained.

### BRIEF DESCRIPTION OF THE DRAWINGS

FIG. 1 is a cross-sectional view schematically showing a rotary electric machine according to a first embodiment;

FIG. 2 is a perspective view showing a major part of the rotary electric machine according to the first embodiment;

FIG. 3 is a cross-sectional view showing the major part of the rotary electric machine according to the first embodiment;

FIG. 4 is a cross-sectional view showing a major part of a rotary electric machine according to a second embodiment;

FIG. 5 is a diagram for explaining disturbance magnetic fluxes around a magnetic detection element in the rotary electric machine according to the second embodiment;

FIG. 6 is a perspective view showing a major part of a rotary electric machine according to a third embodiment;

FIG. 7 is a perspective view showing a major part of another rotary electric machine according to the third embodiment;

FIG. 8 is a cross-sectional view showing a major part of another rotary electric machine according to the third embodiment;

FIG. 9 is a cross-sectional view showing a major part of a rotary electric machine according to a fourth embodiment;

FIG. 10 is a cross-sectional view showing a major part of a rotary electric machine according to a fifth embodiment;

FIG. 11 is a cross-sectional view showing a major part of another rotary electric machine according to the fifth embodiment; and

FIG. 12 is a cross-sectional view showing a major part of another rotary electric machine according to the fifth embodiment.

### DETAILED DESCRIPTION OF THE PREFERRED

### Embodiments of the Invention

Hereinafter, rotation angle detection devices and rotary electric machines according to embodiments of the present disclosure will be described with reference to the drawings. Description will be given while the same or corresponding members and parts in the drawings are denoted by the same reference characters.

### First Embodiment

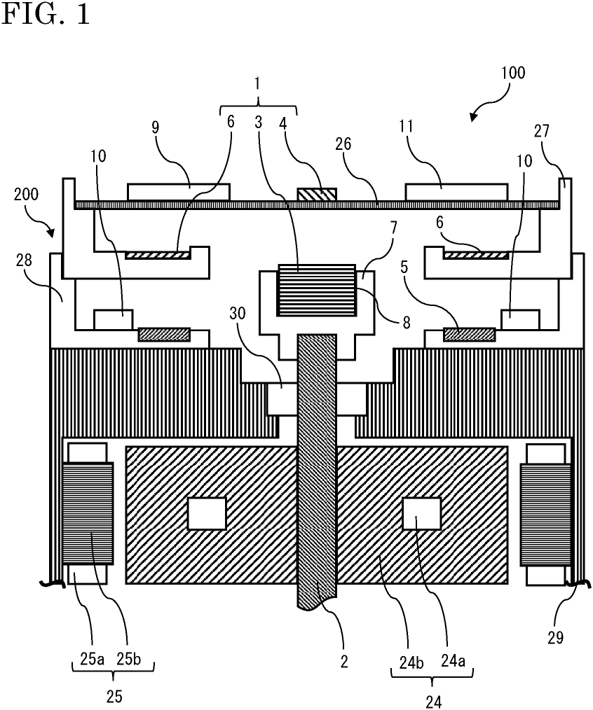

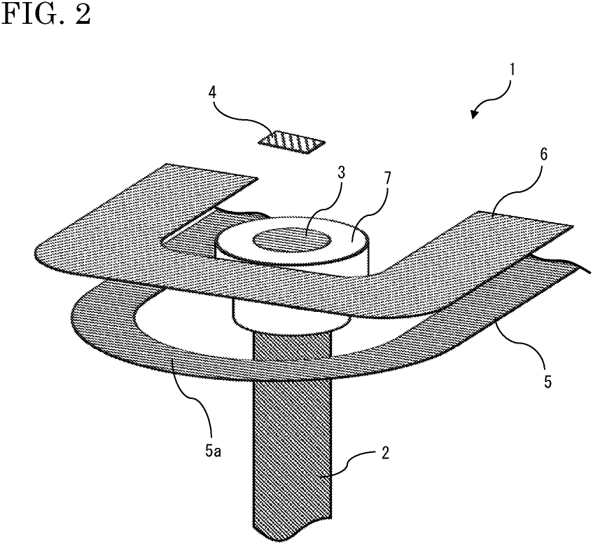

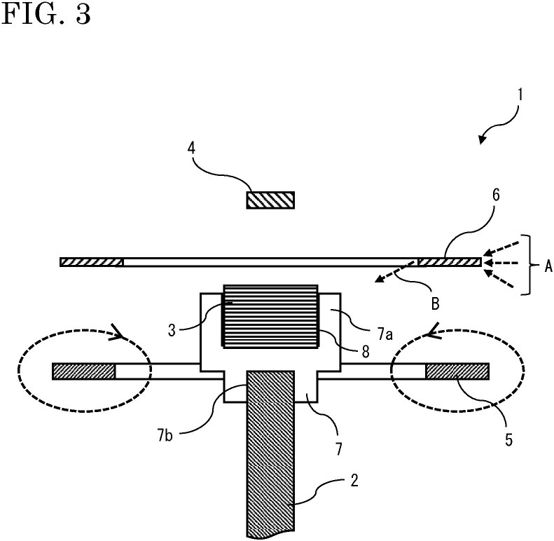

FIG. 1 is a cross-sectional view schematically showing a rotary electric machine 100 according to a first embodiment and is a diagram obtained by cutting the rotary electric machine 100 in an axial direction. FIG. 2 is a perspective view showing a major part of the rotary electric machine 100 and is an enlarged view of a part around a rotation angle detection device 1. FIG. 3 is a cross-sectional view showing the major part of the rotary electric machine 100 and is a diagram obtained by cutting FIG. 2 in the axial direction. In FIG. 1, a portion of the rotary electric machine 100 on another side in the axial direction is not shown. As shown in FIG. 1, the rotary electric machine 100 is a control device-integrated rotary electric machine including, in addition to a body portion of the rotary electric machine 100, a power conversion device 200 which is a control device. Although the control device-integrated rotary electric machine will be described below, the configurations that will be described are applicable to other rotary electric machines having the functions of a power generator and an electric motor. The rotation angle detection device 1 is applicable not only to rotation detection for a rotary electric machine but also to rotation detection for a rotating member to which a wire member allowing current to flow therethrough is adjacently provided.

### Rotary Electric Machine 100

The rotary electric machine 100 includes: the body portion of the rotary electric machine 100; the power conversion device 200; and the rotation angle detection device 1. As shown in FIG. 1, the power conversion device 200 is disposed on one side in the axial direction of a bracket 29 which is a part of the body portion of the rotary electric machine 100, and the power conversion device 200 is fixed to the bracket 29. Firstly, the body portion of the rotary electric machine 100 will be described. The body portion of the rotary electric machine 100 includes: a shaft 2; a rotor 24 which rotates integrally with the shaft 2; a stator 25 disposed outward of the rotor 24; and the bracket 29 which accommodates these members and by which the shaft 2 is rotatably held.

The rotor 24 includes: a field winding 24a; and a field core 24b around which the field winding 24a is wound. The stator 25 disposed radially outward of the rotor 24 includes: multiphase armature windings 25a; and a stator core 25b around which each armature winding 25a is wound. The multiphase armature windings 25a are, for example, one set of three-phase armature windings or two sets of three-phase armature windings. However, the armature windings 25a are not limited thereto and can be set according to the type of the rotary electric machine.

The bracket 29 serving as a housing covers an outer side of each of the rotor 24 and the stator 25. The bracket 29 holds one end side and another end side of the shaft 2 via bearings 30. In FIG. 1, since the portion of the rotary electric machine 100 on the other side in the axial direction is not shown, the bearing via which the other end side of the shaft 2 is held, is not shown. From the viewpoint of weight reduction and productivity, the bracket 29 is made through, for example, aluminum die casting.

### Power Conversion Device 200

The power conversion device 200 converts, into AC power, DC power from an on-board battery (not shown) which is an external DC power supply. Meanwhile, the power conversion device 200 converts, into DC power, AC power from each armature winding 25a. As shown in FIG. 1, the power conversion device 200 includes: power circuit portions 10 on which two sets of three-phase AC circuits are formed; a field circuit portion 11 which supplies field current to the field winding 24a of the rotor 24; and a control circuit portion 9 which is disposed on a control circuit board 26 and which controls each power circuit portion 10 and the field circuit portion 11. The power conversion device 200 further includes: wire members allowing current to flow therethrough and electrically connecting these portions to one another; and cases 27 and 28 accommodating these members. The case 27 accommodates the control circuit board 26 on which the field circuit portion 11 and the control circuit portion 9 are disposed. The case 28 accommodates the power circuit portion 10 and a busbar 5 which is one of the wire members.

The power conversion device 200 is attached to the bracket 29 at the case 28. The power circuit portions 10 have switching elements (not shown) that perform switching between ON and OFF for currents to be supplied to the armature windings 25a. The field circuit portion 11 has switching elements (not shown) that perform switching between ON and OFF for current to be supplied to the field winding 24a. The busbar 5 connects: a power supply terminal (not shown), of the power conversion device 200, that is connected to the on-board battery; and each switching element of the power circuit portions 10. The busbar 5 is formed from a metal having excellent heat conductivity and having electrical conductivity, such as copper or aluminum. Although the busbar 5 is formed in the shape of a sheet in FIG. 2, the shape of the busbar 5 is not limited to the shape of a sheet and may be the shape of a rod.

The armature windings 25a of the stator 25 are formed as, for example, two sets of three-phase armature windings having phases that differ from each other by 30 degrees. These three-phase armature windings are independently controlled by the respective power circuit portions 10 including two sets of three-phase power conversion circuits. Terminals, for respective phases, of the three-phase armature windings 25a arranged in Y connection are connected to AC-side terminals of the power conversion circuits composed of six of the switching elements of the power circuit portions 10. DC-side terminals of the power circuit portions 10 are connected to the power supply terminal and a smoothing capacitor (not shown). Each of the switching elements composing the power circuit portions 10 is an element capable of switching, such as a metal oxide semiconductor field effect transistor (MOSFET).

The field circuit portion 11 has two switching elements, and the two switching elements are connected to the on-board battery. The switching elements of the field circuit portion 11 are mounted on the control circuit board 26. The field circuit portion 11 may be accommodated in the case 28 without mounting the field circuit portion 11 on the control circuit board 26. However, if the field circuit portion 11 is mounted on the control circuit board 26 as in the present embodiment, the size of the power conversion device 200 can be reduced as compared to the case where the field circuit portion 11 is configured separately from the control circuit board 26.

The cases 27 and 28 are each formed from an insulative resin material. The resin material is, for example, polyphenylene sulfide. The case 27 has a waterproof structure tightly sealed with a waterproof cover (not shown) or the like in order to prevent salt and muddy water from entering the accommodated control circuit board 26 and the like.

### Rotation Angle Detection Device 1

The rotation angle detection device 1 which is a major part of the present disclosure will be described. As shown in FIG. 2, the rotation angle detection device 1 includes a magnet 3, a magnetic detection element 4, and a shield 6 formed from a magnetic material. The magnetic detection element 4 detects a signal magnetic flux which is a magnetic flux having flowed out from the magnet 3 rotating together with the shaft 2, whereby the rotation angle detection device 1 detects a rotation angle and a rotation speed of each of the shaft 2 and the rotor 24. The shield 6 reduces disturbance magnetic fluxes heading for the magnetic detection element 4. Reduction of disturbance magnetic fluxes will be described later.

The magnet 3 is provided to an end portion of the shaft 2 with a holder 7 therebetween, the end portion being located on the power conversion device 200 side which is the one side. The magnetic detection element 4 which detects a signal magnetic flux from the magnet 3 is fixed to the control circuit board 26 which faces the magnet 3. The side on which the magnetic detection element 4 is fixed to the control circuit board 26 may be either the one side or the other side of the control circuit board 26. Although the magnetic detection element 4 is fixed to the control circuit board 26 in the present embodiment, the present disclosure is not limited thereto. The magnetic detection element 4 may be fixed to a separate circuit board on which a rotation angle detection circuit is mounted, and the circuit board to which the magnetic detection element 4 is fixed may be connected to the control circuit board 26. However, if the magnetic detection element 4 is fixed to the control circuit board 26, and the rotation angle detection circuit is mounted on the control circuit board 26, it becomes unnecessary to provide any separate circuit board to which the magnetic detection element 4 is fixed, whereby the size of the rotary electric machine 100 can be reduced, and cost therefor can be reduced. In addition, it becomes unnecessary to make connection between the control circuit board 26 and the circuit board to which the magnetic detection element 4 is fixed, whereby productivity for the rotary electric machine 100 can be improved. In addition, since cost for the rotary electric machine 100 can be reduced, and productivity for the rotary electric machine 100 is improved, a rotary electric machine 100 that is excellently economical can be obtained.

Each constituent of the rotation angle detection device 1 will be described. The magnet 3 is provided on the one side in the axial direction of the shaft 2 and rotates integrally with the shaft 2. The magnet 3 is a permanent magnet. The magnet 3 has different magnetic poles in a direction perpendicular to the axial direction. Although the magnet 3 is held by the holder 7 in the present embodiment, fixation of the magnet 3 to the shaft 2 is not limited to fixation performed via the holder 7. The magnet 3 may be directly attached to the shaft 2.

The holder 7 is a member that fixes the magnet 3 to the shaft 2. As shown in FIG. 3, the holder 7 is fixed to the end portion on the one side in the axial direction of the shaft 2, extends from the shaft 2 to the one side in the axial direction, and holds the magnet 3. The holder 7 is formed from a magnetic material such as permalloy or ferrite. The material of the holder 7 is not limited to a magnetic material and may be a resin material.

The holder 7 has a tubular circumferential wall 7a covering the radially outer side of the magnet 3 with a gap interposed therebetween. The gap between the radially outer side of the magnet 3 and the circumferential wall 7a is filled with a fixation member 8 so that the magnet 3 is fixed to the holder 7. The fixation member 8 is, for example, an adhesive or a resin member. With this configuration, the fixation member 8 is not provided on the other side in the axial direction of the magnet 3, and thus uneven filling with the fixation member 8 on the other side in the axial direction of the magnet 3 is not performed. Consequently, it is possible to inhibit the magnet 3 from being fixed so as to be tilted from the axial direction. Since it is possible to inhibit the magnet 3 from being fixed so as to be tilted, signal magnetic fluxes from the magnet 3 can be appropriately directed to the magnetic detection element 4. In addition, signal magnetic fluxes heading for the magnetic detection element 4 can be inhibited from being reduced as a result of being guided to the shield 6. The manner of fixing the magnet 3 to the holder 7 is not limited thereto, and the magnet 3 may be press-fitted in the holder 7 so that both the holder 7 and the magnet 3 are fitted to be fixed to each other, without providing any gap between the holder 7 and the magnet 3. Alternatively, an adhesive may be applied on the radially outer side of the magnet 3, and the magnet 3 may be press-fitted in the holder 7.

The circumferential wall 7a of the holder 7 extends to the one side in the axial direction. If the circumferential wall 7a is formed from a magnetic material, the height in the axial direction of the circumferential wall 7a is set to a height that is not equal to the height in the axial direction of the magnet 3. In the present embodiment, the height in the axial direction of the circumferential wall 7a is set to be lower than the height in the axial direction of the magnet 3. With this configuration, signal magnetic fluxes having flowed out from the magnet 3 can be inhibited from being reduced as a result of being guided to the circumferential wall 7a. A recess 7b resulting from recessing to the one side in the axial direction is provided in an end portion on the other side in the axial direction of the holder 7, and the end portion on the one side in the axial direction of the shaft 2 is fitted in the recess 7b. The manner of fixing the holder 7 to the shaft 2 is not limited thereto, and, with a gap interposed therebetween, the holder 7 and the shaft 2 may be fixed to each other by means of an adhesive.

The magnetic detection element 4 is disposed on the one side in the axial direction relative to the magnet 3 with a gap interposed between the magnetic detection element 4 and the magnet 3. The magnetic detection element 4 is, for example, a magnetoresistive effect element, has a magnetic detection direction perpendicular to the axial direction, and outputs an electrical signal that is based on a detected signal magnetic flux. The magnetic detection element 4 has no sensitivity in any direction that is parallel to the axial direction and that is the up-down direction in the sheet surface of FIG. 3. If the magnetic detection element 4 has a magnetic detection direction perpendicular to the axial direction, influence of a disturbance magnetic flux in the axial direction during detection of a rotation angle and a rotation speed can be suppressed. The magnetic detection direction of the magnetic detection element 4 is not limited to the direction perpendicular to the axial direction, and the magnetic detection direction may be, for example, the direction parallel to the axial direction if the disposition location of the magnetic detection element 4 is changed. The magnetic detection element 4 is, specifically, a Hall element, a giant magneto resistive (GMR) element, an anisotropic magneto resistive (AMR) element, or a tunnel magneto resistive (TMR) element. The number of the magnetic detection elements 4 is not limited to one, and a plurality of the elements may be used in combination. Further, any element may be selected according to a usage environment or the like.

Although a configuration in which the detection circuit connected to the magnetic detection element 4 is mounted on the control circuit board 26 has been described in the present embodiment, the present disclosure is not limited to this configuration. A chip in which the magnetic detection element 4 and the detection circuit are integrated with each other may be fixed at a location, of the control circuit board 26, that faces the magnet 3. The magnet 3 has been magnetized such that, when the magnet 3 rotates together with the shaft 2, the direction of a magnetic field is changed to a direction in which the magnetic detection element 4 has sensitivity. Examples of the magnetization performed on the magnet 3 so as to change the direction of the magnetic field in this manner include: two-pole magnetization on one surface, in which magnetization is performed to obtain one S pole and one N pole; magnetization in the radial direction; and four-pole magnetization on both surfaces.

The shield 6 is disposed at a location in the axial direction between the location in the axial direction of the busbar 5 allowing current to flow therethrough and the location in the axial direction of the magnetic detection element 4. The shield 6 is disposed radially outward of the magnet 3 as seen in the axial direction. The shield 6 is formed from a magnetic material such as a steel plate cold commercial (SPCC) or an electromagnetic steel sheet. The busbar 5 is disposed at a location in the axial direction that is closer to the magnet 3 than the magnetic detection element 4 is, and is disposed radially outward of the magnet 3 as seen in the axial direction. The shield 6 has a portion that overlaps with the busbar 5 as seen in the axial direction.

In the present embodiment, as shown in FIG. 2, the busbar 5 has a circumferentially-extending portion 5a extending in a circumferential direction, and the shield 6 has a portion extending in the circumferential direction so as to overlap with the circumferentially-extending portion 5a as seen in the axial direction. With this configuration, the size of the rotation angle detection device 1 can be reduced in the radial direction. Further, in the present embodiment, the busbar 5 is formed in the shape of a sheet curved on a same plane perpendicular to the axial direction, a surface of the sheet being perpendicular to the axial direction, and the shield 6 is formed in the shape of a sheet curved on a same plane perpendicular to the axial direction, a surface of the sheet being perpendicular to the axial direction. With this configuration, the size of the rotation angle detection device 1 can be reduced in the axial direction.

### Disturbance Magnetic Fluxes and Reduction Thereof

Disturbance magnetic fluxes related to the accuracies of rotation speed detection and rotation angle detection will be described first. The magnetic detection element 4 detects, in the magnetic detection direction, a signal magnetic flux having flowed out from the magnet 3 so that an angular signal of each of the shaft 2 and the rotor 24 is generated. Therefore, magnetic fluxes other than signal magnetic fluxes having flowed out from the magnet 3 are disturbance magnetic fluxes which are not to be detected by the magnetic detection element 4. If a disturbance magnetic flux is included among magnetic fluxes that enter the magnetic detection element 4, an error is generated in an output signal from the magnetic detection element 4. In this case, a rotation angle is calculated by using the erroneous output signal, and thus the error is included in the obtained rotation angle. Consequently, adverse influence is inflicted on control and characteristics of the rotary electric machine 100.

Disturbance magnetic flux in the present embodiment is a magnetic flux based on current flowing through the busbar 5. When current is conducted through the busbar 5, magnetic fluxes having magnitudes based on the amount of the flowing current are generated around the busbar 5 as indicated by broken-line arrows in FIG. 3. When the magnetic fluxes reach the magnetic detection element 4, the magnetic fluxes interlink with the magnetic detection element 4 as disturbance magnetic fluxes.

Reduction of disturbance magnetic fluxes will be described. Since the shield 6 is formed from a magnetic material, the shield 6 has a lower magnetic resistance than air, resin, and the like. Magnetic fluxes are distributed so as to pass through routes in which the magnetic resistances are low. Considering this, the shield 6 is disposed between the busbar 5 and the magnetic detection element 4, whereby the disturbance magnetic fluxes generated around the busbar 5 can be guided to the shield 6. In FIG. 3, disturbance magnetic fluxes guided to the shield 6 are indicated by arrows A. In the drawing, although the arrows A are indicated only on the right side of the shield 6, disturbance magnetic fluxes are guided also to the left side of the shield 6 in the same manner. If the holder 7 is formed from a magnetic material, a disturbance magnetic flux having flowed out from the shield 6 heads for the holder 7. In FIG. 3, the disturbance magnetic flux heading for the holder 7 from the shield 6 is indicated by an arrow B. Even if the holder 7 is not formed from a magnetic material, the disturbance magnetic flux does not head in a direction toward the magnetic detection element 4 since no member formed from a magnetic material is disposed on the one side in the axial direction relative to the shield 6.

By thus disposing the shield 6, disturbance magnetic fluxes generated around the busbar 5 are guided to the shield 6, whereby disturbance magnetic fluxes that enter the magnetic detection element 4 can be reduced. Since the shield 6 has a portion that overlaps with the busbar 5 as seen in the axial direction, the disturbance magnetic fluxes generated around the busbar 5 can be more effectively guided to the shield 6, and influence of the disturbance magnetic fluxes that enter the magnetic detection element 4 can be suppressed. Since the influence of the disturbance magnetic fluxes that enter the magnetic detection element 4 is suppressed, reduction of the accuracies of rotation speed detection and rotation angle detection which are performed by the rotation angle detection device 1 can be prevented. In addition, since reduction of the accuracies of rotation speed detection and rotation angle detection can be prevented, reduction of the power generation efficiency or the drive efficiency of the rotary electric machine 100 is suppressed. Consequently, a highly-efficient rotary electric machine 100 can be obtained.

The shield 6 is disposed radially outward of the magnet 3 as seen in the axial direction. Therefore, guidance, to the shield 6, of signal magnetic fluxes generated from the magnet 3 can be suppressed. Since guidance of the signal magnetic fluxes to the shield 6 is suppressed, reduction of signal magnetic fluxes that enter the magnetic detection element 4 in the magnetic detection direction thereof can be suppressed. In the present embodiment, a portion on the radially inner side of the shield 6 is opened. This opening may be covered by a nonmagnetic member formed from resin or the like. If the shield 6 is molded from a resin material and attached to the case 27, assemblability of the rotary electric machine 100 is improved, whereby productivity for the rotary electric machine 100 can be improved.

In the present embodiment, the shield 6 is disposed at a location in the axial direction between the location in the axial direction of the magnet 3 and the location in the axial direction of the magnetic detection element 4. Therefore, guidance, to the shield 6, of signal magnetic fluxes generated from the magnet 3 can be further suppressed. Since guidance of the signal magnetic fluxes to the shield 6 is further suppressed, reduction of signal magnetic fluxes that enter the magnetic detection element 4 can be further suppressed.

In the present embodiment, the distance in the axial direction between the location in the axial direction of the shield 6 and the location in the axial direction of the magnetic detection element 4 is shorter than the distance in the axial direction between the location in the axial direction of the shield 6 and the location in the axial direction of the busbar 5. Consequently, disturbance magnetic fluxes generated around the busbar 5 can be more effectively guided to the shield 6, and disturbance magnetic fluxes that enter the magnetic detection element 4 can be reduced.

In the present embodiment, the width in the axial direction of the shield 6 is smaller than the width in the radial direction of the shield 6. Therefore, guidance, to the shield 6, of signal magnetic fluxes generated from the magnet 3 can be suppressed. Since guidance of the signal magnetic fluxes to the shield 6 is suppressed, reduction of signal magnetic fluxes that enter the magnetic detection element 4 can be suppressed.

As described above, the rotation angle detection device 1 according to the first embodiment includes: the magnet 3 which rotates integrally with the shaft 2; the magnetic detection element 4 disposed with a gap interposed between the magnetic detection element 4 and the magnet 3; and the shield 6 formed from a magnetic material. The shield 6 is disposed at a location in the axial direction between the location in the axial direction of the busbar 5 allowing current to flow therethrough and the location in the axial direction of the magnetic detection element 4, is disposed radially outward of the magnet 3 as seen in the axial direction, and has a portion that overlaps with the busbar 5 as seen in the axial direction. The busbar 5 is disposed at a location in the axial direction that is closer to the magnet 3 than the magnetic detection element 4 is, and is disposed radially outward of the magnet 3 as seen in the axial direction. Consequently, disturbance magnetic fluxes generated around the busbar 5 are guided to the shield 6, and disturbance magnetic fluxes that enter the magnetic detection element 4 are reduced. Therefore, influence of the disturbance magnetic fluxes that enter the magnetic detection element 4 in the magnetic detection direction thereof is suppressed, whereby reduction of the accuracies of rotation speed detection and rotation angle detection can be prevented. In addition, the shield 6 is disposed radially outward of the magnet 3 as seen in the axial direction, and guidance, to the shield 6, of signal magnetic fluxes generated from the magnet 3 is suppressed. Consequently, reduction of signal magnetic fluxes that enter the magnetic detection element 4 in the magnetic detection direction thereof is suppressed, whereby reduction of the accuracies of rotation speed detection and rotation angle detection can be prevented.

If the busbar 5 has the circumferentially-extending portion 5a extending in the circumferential direction, and the shield 6 has a portion extending in the circumferential direction so as to overlap with the circumferentially-extending portion 5a as seen in the axial direction, the size of the rotation angle detection device 1 can be reduced in the radial direction. Further, if the busbar 5 is formed in the shape of a sheet curved on the same plane perpendicular to the axial direction, a surface of the sheet being perpendicular to the axial direction, and the shield 6 is formed in the shape of a sheet curved on the same plane perpendicular to the axial direction, a surface of the sheet being perpendicular to the axial direction, the size of the rotation angle detection device 1 can be reduced in the axial direction.

If the shield 6 is disposed at a location in the axial direction between the location in the axial direction of the magnet 3 and the location in the axial direction of the magnetic detection element 4, guidance, to the shield 6, of signal magnetic fluxes generated from the magnet 3 is further suppressed. Consequently, reduction of signal magnetic fluxes that enter the magnetic detection element 4 can be further suppressed. In addition, if the distance in the axial direction between the location in the axial direction of the shield 6 and the location in the axial direction of the magnetic detection element 4 is shorter than the distance in the axial direction between the location in the axial direction of the shield 6 and the location in the axial direction of the busbar 5, disturbance magnetic fluxes generated around the busbar 5 can be more effectively guided to the shield 6, and disturbance magnetic fluxes that enter the magnetic detection element 4 can be reduced.

If the width in the axial direction of the shield 6 is smaller than the width in the radial direction of the shield 6, guidance, to the shield 6, of signal magnetic fluxes generated from the magnet 3 is suppressed. Consequently, reduction of signal magnetic fluxes that enter the magnetic detection element 4 can be suppressed. In addition, if the magnetic detection element 4 is a magnetoresistive effect element having a magnetic detection direction perpendicular to the axial direction, influence of disturbance magnetic fluxes in the axial direction during detection of a rotation angle and a rotation speed can be suppressed.

If the holder 7 holding the magnet 3 is provided, the holder 7 has the tubular circumferential wall 7a covering the radially outer side of the magnet 3 with a gap interposed therebetween, and the gap between the radially outer side of the magnet 3 and the circumferential wall 7a is filled with the fixation member 8, the fixation member 8 is not provided on the other side in the axial direction of the magnet 3, and thus uneven filling with the fixation member 8 on the other side in the axial direction of the magnet 3 is not performed. Consequently, it is possible to inhibit the magnet 3 from being fixed so as to be tilted in the axial direction.

The rotary electric machine 100 according to the first embodiment includes: the rotation angle detection device 1 according to the present disclosure; the shaft 2; the busbar 5; the rotor 24 which rotates integrally with the shaft 2 and which has the field winding 24a and the field core 24b around which the field winding 24a is wound; the stator 25 disposed radially outward of the rotor 24 and having the stator core 25b around which each armature winding 25a is wound; and the bracket 29 covering the outer side of each of the rotor 24 and the stator 25 and holding the one end side and the other end side of the shaft 2 via the bearings 30. Consequently, disturbance magnetic fluxes generated around the busbar 5 are guided to the shield 6, whereby influence of disturbance magnetic fluxes that enter the magnetic detection element 4 in the magnetic detection direction thereof is suppressed. Furthermore, guidance, to the shield 6, of signal magnetic fluxes generated from the magnet 3 is suppressed. Therefore, reduction of the accuracies of rotation speed detection and rotation angle detection is prevented, whereby a highly-efficient rotary electric machine 100 can be obtained.

### Second Embodiment

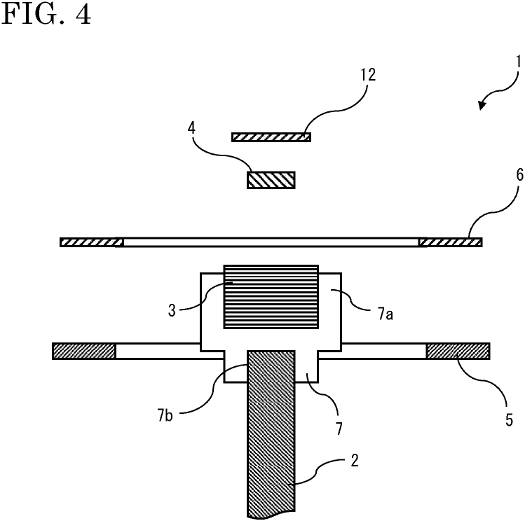

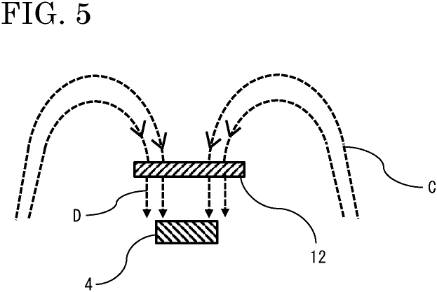

A rotation angle detection device 1 according to a second embodiment will be described. FIG. 4 is a cross-sectional view showing a major part of a rotary electric machine 100 according to the second embodiment and is a diagram obtained by enlarging a part around the rotation angle detection device 1 and cutting the part in the axial direction. FIG. 5 is a diagram for explaining disturbance magnetic fluxes around the magnetic detection element 4. The rotation angle detection device 1 according to the second embodiment includes an additional shield 12 in addition to the constituents in the first embodiment.

A configuration in which disturbance magnetic fluxes generated around the busbar 5 are reduced has been described in the first embodiment. Meanwhile, a configuration in which disturbance magnetic fluxes generated around the shaft 2 are reduced will be described in the second embodiment. In the present embodiment, the shaft 2 is formed from a magnetic material such as an alloy that contains iron as a main component. Current is conducted through the field winding 24a so as to follow a circular route extending in the circumferential direction around the shaft 2. Consequently, magnetic fluxes generated by the conduction made through the field winding 24a pass in the axial direction of the shaft 2. Thus, the magnetic fluxes having passed through the shaft 2 flow out from the end portion of the shaft 2, and the magnetic fluxes having flowed out become disturbance magnetic fluxes. When current is conducted through the field winding 24a, the disturbance magnetic fluxes are generated as indicated by broken-line arrows (arrows C) in FIG. 5. If the additional shield 12 is not provided, the disturbance magnetic fluxes reach the magnetic detection element 4 and interlink with the magnetic detection element 4. If the disturbance magnetic fluxes enter the magnetic detection element 4 in a state of having many components in the magnetic detection direction of the magnetic detection element 4, an error is generated in the output signal from the magnetic detection element 4, whereby the accuracies of the rotation angle and the rotation speed are reduced.

The rotation angle detection device 1 includes the additional shield 12 disposed on the one side in the axial direction relative to the magnetic detection element 4 with a gap interposed between the additional shield 12 and the magnetic detection element 4. The additional shield 12 is formed from a magnetic material such as a steel plate cold commercial (SPCC) or an electromagnetic steel sheet. The magnetic detection direction of the magnetic detection element 4 is perpendicular to the axial direction. The magnetic detection element 4 is, for example, a magnetoresistive effect element. Since the additional shield 12 is provided, disturbance magnetic fluxes generated around the shaft 2 are guided to the additional shield 12. Disturbance magnetic fluxes having flowed out from the additional shield 12 head in directions toward the shaft 2. In FIG. 5, the disturbance magnetic fluxes heading in the directions toward the shaft 2 from the additional shield 12 are indicated by arrows D. The disturbance magnetic fluxes indicated by the arrows D are parallel to the axial direction. The magnetic detection element 4 has no sensitivity in any direction parallel to the axial direction, and thus does not detect any of the disturbance magnetic fluxes indicated by the arrows D.

By thus disposing the additional shield 12, disturbance magnetic fluxes generated around the shaft 2 are guided to the additional shield 12, and disturbance magnetic fluxes having flowed out from the additional shield 12 become parallel to the axial direction. Consequently, disturbance magnetic fluxes that enter the magnetic detection element 4 in the magnetic detection direction thereof can be reduced. Since influence of the disturbance magnetic fluxes that enter the magnetic detection element 4 is suppressed, reduction of the accuracies of rotation speed detection and rotation angle detection which are performed by the rotation angle detection device 1 can be prevented. In addition, since reduction of the accuracies of rotation speed detection and rotation angle detection can be prevented, reduction of the power generation efficiency or the drive efficiency of the rotary electric machine 100 is suppressed. Consequently, a highly-efficient rotary electric machine 100 can be obtained.

In the present embodiment, the additional shield 12 is formed in the shape of a sheet, and the additional shield 12 is disposed such that a surface of the sheet thereof is perpendicular to the axial direction. With this configuration, the size of the rotation angle detection device 1 can be reduced in the axial direction, and the disturbance magnetic fluxes having flowed out from the additional shield 12 can be aligned so as to be more parallel to the axial direction. Since the disturbance magnetic fluxes having flowed out from the additional shield 12 become more parallel to the axial direction, disturbance magnetic fluxes that enter the magnetic detection element 4 in the magnetic detection direction thereof can be further reduced. It is noted that the shape of the additional shield 12 is not limited to the shape of a sheet and may be another shape such as the shape of a block.

### Third Embodiment

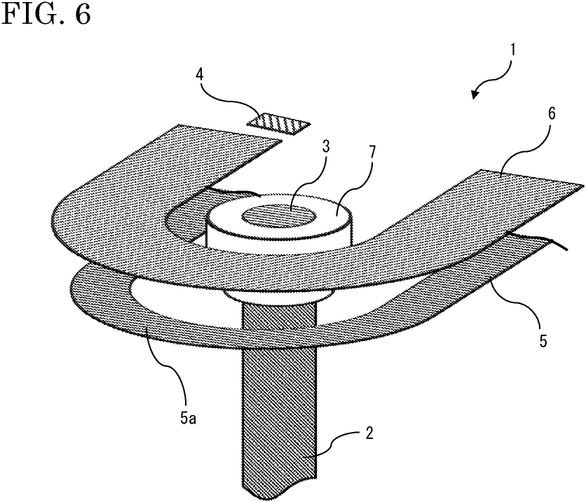

A rotation angle detection device 1 according to a third embodiment will be described. FIG. 6 is a perspective view showing a major part of a rotary electric machine 100 according to the third embodiment and is an enlarged view of a part around the rotation angle detection device 1. The rotation angle detection device 1 according to the third embodiment has a configuration different from the configuration in the first embodiment in terms of the shape of the shield 6.

In the rotation angle detection device 1 described in the first embodiment, if the shape of the shield 6 formed from a magnetic material is significantly different from the shape of the busbar 5, the amount of disturbance magnetic fluxes that are generated around the busbar 5 and that are guided to the shield 6 varies among portions of the shield 6. Consequently, variation is generated in a distribution of disturbance magnetic fluxes around the magnetic detection element 4. If variation is generated in the distribution of the disturbance magnetic fluxes around the magnetic detection element 4, unevenness occurs among disturbance magnetic fluxes that enter the magnetic detection element 4, whereby it becomes difficult to reduce disturbance magnetic fluxes by correcting an output from the magnetic detection element 4. Since it is difficult to reduce disturbance magnetic fluxes, an influence of the disturbance magnetic fluxes is superimposed on the output from the magnetic detection element 4. Consequently, an error is added to the output from the magnetic detection element 4, whereby the accuracies of rotation speed detection and rotation angle detection which are performed by the rotation angle detection device 1 are reduced. It is noted that, if the disturbance magnetic fluxes are evenly distributed, influence of the disturbance magnetic fluxes can be further suppressed by correcting the output from the magnetic detection element 4.

In the present embodiment, the shape of the shield 6 is similar to the shape of the busbar 5 around the shaft 2 as seen in the axial direction, and the shield 6 and the busbar 5 overlap with each other as seen in the axial direction. If the busbar 5 is provided so as to have an annular portion throughout which the gap between the shaft 2 and the radially inner side of the circumferentially-extending portion 5a is even, the shield 6 having a shape similar to that of the busbar 5 is provided so as to have, for example, a portion that is similar to the annular portion of the busbar 5 and that overlaps with the annular portion of the busbar 5 as seen in the axial direction. The shape of the shield 6 is similar also to the shapes of portions of the busbar 5 that extend from the annular portion of the busbar 5, and the shield 6 has portions that, as seen in the axial direction, overlap also with the portions of the busbar 5 that extend from the annular portion of the busbar 5.

Since the shape of the shield 6 is similar to the shape of the busbar 5 around the shaft 2, and the shield 6 and the busbar 5 overlap with each other as seen in the axial direction, disturbance magnetic fluxes are distributed around the busbar 5. Consequently, the disturbance magnetic fluxes are evenly guided to the shield 6. Since the disturbance magnetic fluxes are evenly guided to the shield 6, the disturbance magnetic fluxes are evenly reduced. Consequently, disturbance magnetic fluxes that enter the magnetic detection element 4 can be evenly reduced. Since influence of the disturbance magnetic fluxes that enter the magnetic detection element 4 is suppressed, reduction of the accuracies of rotation speed detection and rotation angle detection which are performed by the rotation angle detection device 1 can be prevented. In addition, since the disturbance magnetic fluxes that enter the magnetic detection element 4 are evenly reduced, the disturbance magnetic fluxes are further reduced by correcting the output from the magnetic detection element 4, whereby the accuracies of rotation speed detection and rotation angle detection can be further improved.

### Modification 1

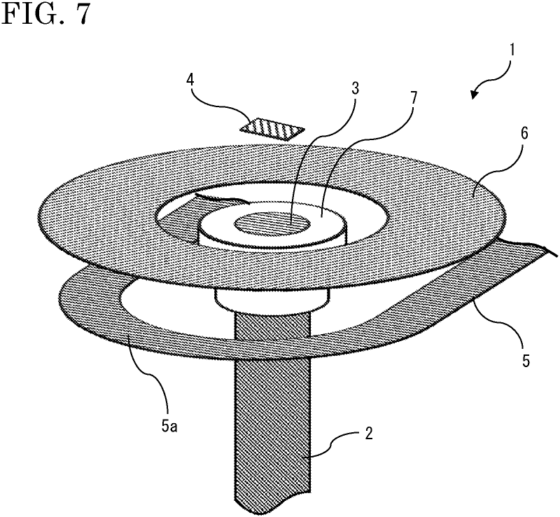

A modification of the shape of the shield 6 will be described. FIG. 7 is a perspective view showing a major part of another rotary electric machine 100 according to the third embodiment and is an enlarged view of a part around the rotation angle detection device 1. The shield 6 has an annular shape extending in the circumferential direction. With this configuration, asymmetry in a distribution of disturbance magnetic fluxes around the magnetic detection element 4 can be further mitigated, and the disturbance magnetic fluxes around the magnetic detection element 4 can be further evenly reduced in the distribution thereof. Consequently, influence of disturbance magnetic fluxes that enter the magnetic detection element 4 is further suppressed, whereby reduction of the accuracies of rotation speed detection and rotation angle detection which are performed by the rotation angle detection device 1 can be further prevented. In addition, since the disturbance magnetic fluxes that enter the magnetic detection element 4 are further evenly reduced, the disturbance magnetic fluxes are further reduced by correcting the output from the magnetic detection element 4, whereby the accuracies of rotation speed detection and rotation angle detection can be further improved.

### Modification 2

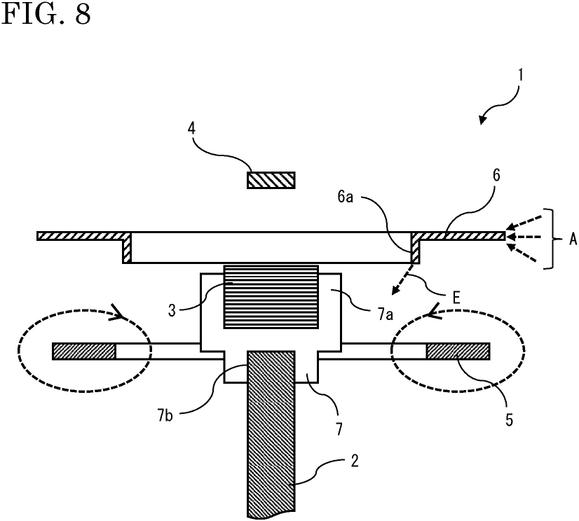

Another modification of the shape of the shield 6 will be described. FIG. 8 is a cross-sectional view showing a major part of another rotary electric machine 100 according to the third embodiment and is a diagram obtained by enlarging a part around the rotation angle detection device 1 and cutting the part in the axial direction. An end portion on the radially inner side of the shield 6 is bent toward the other side in the axial direction. The portion of the shield 6 that is bent toward the other side in the axial direction is a bent portion 6a. With this configuration, a disturbance magnetic flux (arrow E) having flowed out from the shield 6 can be assuredly caused to flow in a direction away from the magnetic detection element 4. Since the disturbance magnetic flux having flowed out from the shield 6 flows in a direction away from the magnetic detection element 4, influence of disturbance magnetic fluxes that enter the magnetic detection element 4 can be further suppressed. Since the influence of the disturbance magnetic fluxes that enter the magnetic detection element 4 is further suppressed, reduction of the accuracies of rotation speed detection and rotation angle detection which are performed by the rotation angle detection device 1 can be further prevented.

Although an angle formed between the bent portion 6a and the body portion of the shield 6 is set to 90° in the present embodiment, the angle is not limited to 90°. The bent portion 6a may be provided, with the angle thereof being changed according to the arrangement of the shield 6 and the busbar 5 or a disturbance magnetic flux reducing effect. Further, although the length in the axial direction of the bent portion 6a is set such that the bent portion 6a extends to the one side in the axial direction of the magnet 3 in the present embodiment, the length in the axial direction of the bent portion 6a is not limited thereto. The length in the axial direction of the bent portion 6a may be such that the bent portion 6a reaches the busbar 5, and the bent portion 6a may be provided, with the length in the axial direction of the bent portion 6a being changed according to the arrangement of the shield 6 and the busbar 5 or the disturbance magnetic flux reducing effect.

### Fourth Embodiment

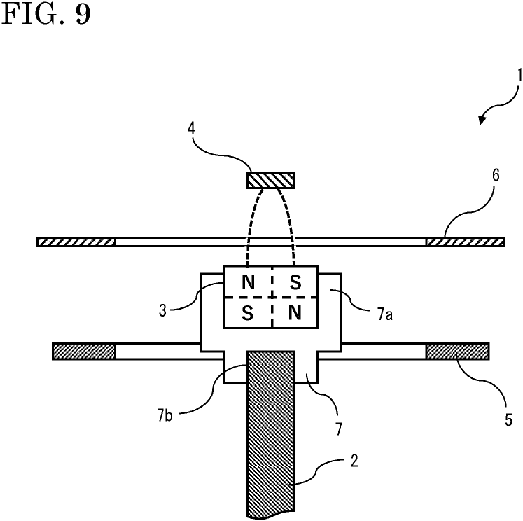

A rotation angle detection device 1 according to a fourth embodiment will be described. FIG. 9 is a cross-sectional view showing a major part of a rotary electric machine 100 according to the fourth embodiment and is a diagram obtained by enlarging a part around the rotation angle detection device 1 and cutting the part in the axial direction. The rotation angle detection device 1 according to the fourth embodiment has a configuration different from the configuration in the first embodiment in terms of the magnetic poles of the magnet 3.

In the rotation angle detection device 1 described in the first embodiment, if the shield 6 formed from a magnetic material is disposed adjacently to the magnet 3 from which signal magnetic fluxes flow out, signal magnetic fluxes having flowed out from the magnet 3 are likely to be guided to the shield 6 having a low magnetic resistance. When the signal magnetic fluxes are guided to the shield 6, signal magnetic fluxes that enter the magnetic detection element 4 are reduced. The reduction in the signal magnetic fluxes leads to reduction in the ratio (S/N ratio) of signal magnetic fluxes to disturbance magnetic fluxes. The reduction in the S/N ratio leads to generation of an error in the output from the magnetic detection element 4. Consequently, the accuracies of rotation speed detection and rotation angle detection which are performed by the rotation angle detection device 1 are reduced.

In the present embodiment, the magnet 3 has N (representing an even number that is two or more) magnetic poles on the one side in the axial direction and has N magnetic poles on the other side in the axial direction. The N magnetic poles of the magnet 3 on the one side in the axial direction and the N magnetic poles of the magnet 3 on the other side in the axial direction are disposed at locations that coincide with each other in the circumferential direction. Two of the magnetic poles that are adjacent in the axial direction are different from each other, and two of the magnetic poles that are adjacent in the circumferential direction are different from each other. By thus configuring the magnetic poles of the magnet 3, magnetic fluxes having flowed out from a side surface of the magnet 3 are distributed in the axial direction. Consequently, radially-outward flow of the signal magnetic fluxes (magnetic fluxes indicated by broken lines in FIG. 9) having flowed out from the magnet 3 can be suppressed. Since the radially-outward flow of the signal magnetic fluxes is suppressed, guidance of the signal magnetic fluxes to the shield 6 is suppressed. Consequently, reduction of the S/N ratio can be suppressed. Since the reduction of the S/N ratio is suppressed, reduction of the accuracies of rotation speed detection and rotation angle detection which are performed by the rotation angle detection device 1 can be prevented.

In addition, the rotation angle detection device 1 in the present embodiment includes the holder 7 fixed to the end portion on the one side in the axial direction of the shaft 2 and holding the magnet 3. The holder 7 has the circumferential wall 7a covering the radially outer side of the magnet 3 and formed from a magnetic material. With this configuration, magnetic fluxes having flowed out from the side surface of the magnet 3 are collected by the circumferential wall 7a. Consequently, the radially-outward flow of the signal magnetic fluxes having flowed out from the magnet 3 can be further suppressed. Since the radially-outward flow of the signal magnetic fluxes is further suppressed, guidance of the signal magnetic fluxes to the shield 6 is further suppressed. Consequently, reduction of the S/N ratio can be further suppressed. Since the reduction of the S/N ratio is further suppressed, reduction of the accuracies of rotation speed detection and rotation angle detection which are performed by the rotation angle detection device 1 can be further prevented.

### Fifth Embodiment

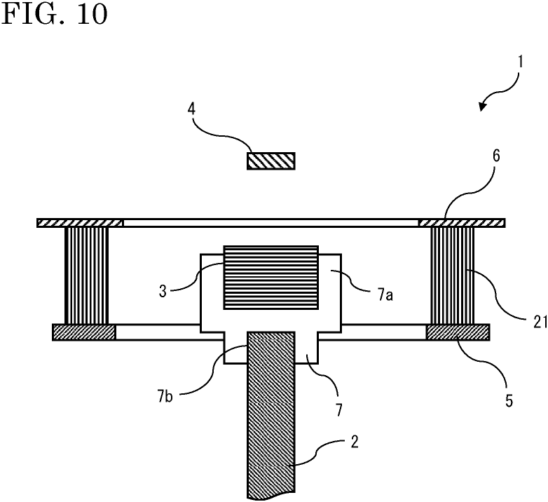

A rotation angle detection device 1 according to a fifth embodiment will be described. FIG. 10 is a cross-sectional view showing a major part of a rotary electric machine 100 according to the fifth embodiment and is a diagram obtained by enlarging a part around the rotation angle detection device 1 and cutting the part in the axial direction. The rotation angle detection device 1 according to the fifth embodiment includes support members 21 in addition to the constituents in the first embodiment.

In the rotation angle detection device 1 described in the first embodiment, if the shield 6 is unexpectedly shifted from the original arrangement owing to vibrations or the like so that the portions of the shield 6 and the busbar 5 that overlap with each other are displaced as seen in the axial direction, variation is generated in a distribution of disturbance magnetic fluxes around the magnetic detection element 4. In addition, since the portions of the shield 6 and the busbar 5 that overlap with each other are displaced as seen in the axial direction, a parameter for correction against influence of disturbance magnetic fluxes changes in an arrangement after the shift of the shield 6 since correction of the output from the magnetic detection element 4 against influence of disturbance magnetic fluxes has been performed in the original arrangement of the shield 6. If there is variation in the distribution of the disturbance magnetic fluxes around the magnetic detection element 4, and the parameter for the correction changes, it becomes difficult to reduce the disturbance magnetic fluxes by correcting the output from the magnetic detection element 4. Since it is difficult to reduce the disturbance magnetic fluxes, an influence of the disturbance magnetic fluxes is superimposed on the output from the magnetic detection element 4. Consequently, an error is added to the output from the magnetic detection element 4, whereby the accuracies of rotation speed detection and rotation angle detection which are performed by the rotation angle detection device 1 are reduced.

In the present embodiment, the rotation angle detection device 1 includes the support members 21 fixing the other side in the axial direction of the shield 6 and the one side in the axial direction of the busbar 5 to each other. Each support member 21 is formed from an insulation material, e.g., a polyphenylene sulfide (PPS) resin, a nylon resin, or an epoxy resin. The shield 6 and the busbar 5 are electrically insulated from each other. The means for fixing the support member 21 is, for example, adhesion. With this configuration, the portions of the shield 6 and the busbar 5 that overlap with each other are not displaced as seen in the axial direction, and thus variation in the distribution of the disturbance magnetic fluxes around the magnetic detection element 4 and a change in the parameter for the correction can be suppressed. Since the variation in the distribution of the disturbance magnetic fluxes around the magnetic detection element 4 and the change in the parameter for the correction are suppressed, and influence of the disturbance magnetic fluxes that enter the magnetic detection element 4 is suppressed, reduction of the accuracies of rotation speed detection and rotation angle detection which are performed by the rotation angle detection device 1 can be prevented. In addition, disturbance magnetic fluxes are reduced by correcting the output from the magnetic detection element 4, whereby the accuracies of rotation speed detection and rotation angle detection which are performed by the rotation angle detection device 1 can be improved.

### Modification 1

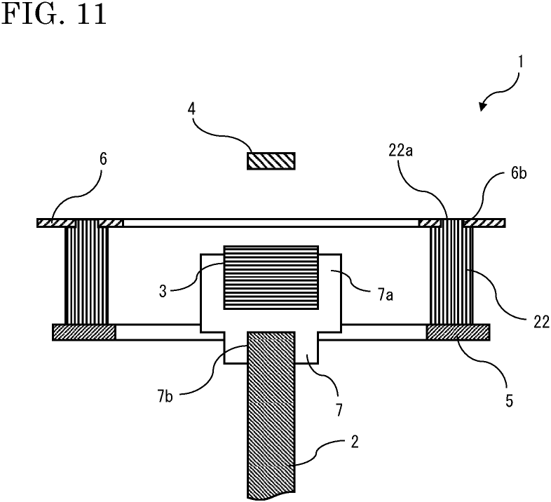

A modification for fixation between the shield 6 and support members 22 will be described. FIG. 11 is a cross-sectional view showing a major part of another rotary electric machine 100 according to the fifth embodiment and is a diagram obtained by enlarging a part around the rotation angle detection device 1 and cutting the part in the axial direction. The shield 6 has a cut into which a fitting portion 22a provided to each support member 22 is fitted. The fitting portion 22a is a portion that projects from the one side in the axial direction of the support member 22 to the one side in the axial direction. The cut is a through hole 6b penetrating the shield 6 in the axial direction. It is noted that the cut is not limited to the through hole 6b and may be, for example, a cut that is formed in the radial direction in an outer circumferential portion of the shield 6. By fitting the fitting portion 22a into the through hole 6b, the support member 22 and the shield 6 are fixed to each other. It is noted that the configuration in which the fitting portion 22a is fitted into the through hole 6b may be obtained by integrally molding the support member 22 and the shield 6.

This configuration makes it possible to further suppress displacement, in the radial direction or the circumferential direction, of the portions of the shield 6 and the busbar 5 that overlap with each other as seen in the axial direction. Since the displacement of the portions of the shield 6 and the busbar 5 that overlap with each other as seen in the axial direction is further suppressed, variation in the distribution of the disturbance magnetic fluxes around the magnetic detection element 4 and a change in the parameter for the correction can be further suppressed. Since the variation in the distribution of the disturbance magnetic fluxes around the magnetic detection element 4 and the change in the parameter for the correction are further suppressed, and influence of the disturbance magnetic fluxes that enter the magnetic detection element 4 is further suppressed, reduction of the accuracies of rotation speed detection and rotation angle detection which are performed by the rotation angle detection device 1 can be further prevented. In addition, disturbance magnetic fluxes are reduced by correcting the output from the magnetic detection element 4, whereby the accuracies of rotation speed detection and rotation angle detection which are performed by the rotation angle detection device 1 can be further improved.

### Modification 2

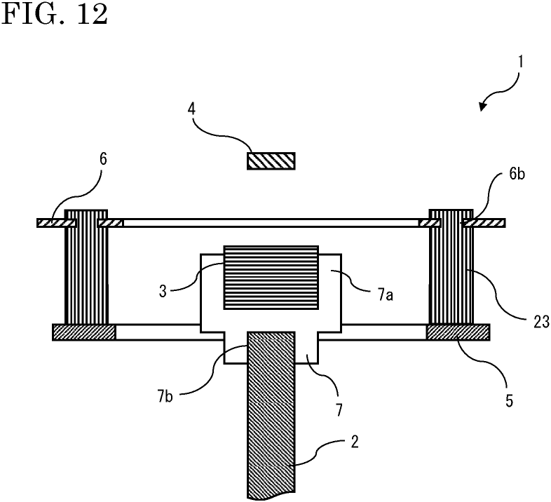

Another modification for fixation between the shield 6 and support members 23 will be described. FIG. 12 is a cross-sectional view showing a major part of another rotary electric machine 100 according to the fifth embodiment and is a diagram obtained by enlarging a part around the rotation angle detection device 1 and cutting the part in the axial direction. The shield 6 has the through holes 6b penetrating therethrough in the axial direction. Each support member 23 is provided at: a portion within the corresponding through hole 6b; and a portion on the one side in the axial direction of the through hole 6b and the shield 6 around the through hole 6b. Around the through hole 6b, the support member 23 is provided at portions on both the one side in the axial direction of the shield 6 and the other side in the axial direction of the shield 6. This configuration is obtained by integrally molding the support member 23 and the shield 6. It is noted that no limitation to integral molding is imposed, and, in this configuration, a portion of the support member 23 that projects from the through hole 6b to the one side in the axial direction may be formed through upsetting. In the case where this configuration is obtained through integral molding, the busbar 5 may also be included. That is, the shield 6, the support member 23, and the busbar 5 may be integrally molded.

This configuration makes it possible not only to suppress displacement, in the radial direction or the circumferential direction, of the portions of the shield 6 and the busbar 5 that overlap with each other as seen in the axial direction, but also to suppress displacement of the shield 6 and the busbar 5 in the axial direction. Since the displacement of the shield 6 and the busbar 5 in the axial direction is suppressed, variation in the distribution of the disturbance magnetic fluxes around the magnetic detection element 4 and a change in the parameter for the correction can be further suppressed. Since the variation in the distribution of the disturbance magnetic fluxes around the magnetic detection element 4 and the change in the parameter for the correction are further suppressed, and influence of the disturbance magnetic fluxes that enter the magnetic detection element 4 is further suppressed, reduction of the accuracies of rotation speed detection and rotation angle detection which are performed by the rotation angle detection device 1 can be further prevented. In addition, disturbance magnetic fluxes are reduced by correcting the output from the magnetic detection element 4, whereby the accuracies of rotation speed detection and rotation angle detection which are performed by the rotation angle detection device 1 can be further improved.

Although the disclosure is described above in terms of various exemplary embodiments and implementations, it should be understood that the various features, aspects, and functionality described in one or more of the individual embodiments are not limited in their applicability to the particular embodiment with which they are described, but instead can be applied, alone or in various combinations to one or more of the embodiments of the disclosure.

It is therefore understood that numerous modifications which have not been exemplified can be devised without departing from the scope of the specification of the present disclosure. For example, at least one of the constituent components may be modified, added, or eliminated. At least one of the constituent components mentioned in at least one of the preferred embodiments may be selected and combined with the constituent components mentioned in another preferred embodiment.

### DESCRIPTION OF THE REFERENCE CHARACTERS

1 rotation angle detection device
2 shaft
3 magnet
4 magnetic detection element
5 busbar
5a circumferentially-extending portion
6 shield
6a bent portion
6b through hole
7 holder
7a circumferential wall
7b recess
8 fixation member
9 control circuit portion
10 power circuit portion
11 field circuit portion
12 additional shield
21, 22, 23 support member
22a fitting portion
24 rotor
24a field winding
24b field core
25 stator
25a armature winding
25b stator core
26 control circuit board
27, 28 case
29 bracket
30 bearing
100 rotary electric machine
200 power conversion device

What is claimed is:

1. A rotation angle detection device comprising:
a magnet provided on one side in an axial direction of a shaft and configured to rotate integrally with the shaft;
a magnetic detection element disposed on the one side in the axial direction relative to the magnet with a gap interposed between the magnetic detection element and the magnet; and
a shield formed from a magnetic material, wherein the shield
is disposed at a location in the axial direction between a location in the axial direction of a wire member allowing current to flow therethrough and a location in the axial direction of the magnetic detection element,
is disposed radially outward of the magnet as seen in the axial direction, and
has a portion that overlaps with the wire member as seen in the axial direction, and
the wire member is
disposed at a location in the axial direction that is closer to the magnet than the magnetic detection element is, and
disposed radially outward of the magnet as seen in the axial direction.

2. The rotation angle detection device according to claim 1, wherein
the wire member has a circumferentially-extending portion extending in a circumferential direction, and
the shield has a portion extending in the circumferential direction so as to overlap with the circumferentially-extending portion as seen in the axial direction.

3. The rotation angle detection device according to claim 2, wherein
the wire member is formed in a shape of a sheet curved on a same plane perpendicular to the axial direction, a surface of the sheet being perpendicular to the axial direction, and
the shield is formed in a shape of a sheet curved on a same plane perpendicular to the axial direction, a surface of the sheet being perpendicular to the axial direction.

4. The rotation angle detection device according to claim 1, further comprising
an additional shield disposed on the one side in the axial direction relative to the magnetic detection element with a gap interposed between the additional shield and the magnetic detection element, wherein
the shaft is formed from a magnetic material through which a magnetic flux passes in the axial direction, and
a magnetic detection direction of the magnetic detection element is perpendicular to the axial direction.

5. The rotation angle detection device according to claim 4, wherein
the additional shield is formed in a shape of a sheet, and
the additional shield is disposed such that a surface of the sheet thereof is perpendicular to the axial direction.

6. The rotation angle detection device according to claim 1, wherein the shield is disposed at a location in the axial direction between a location in the axial direction of the magnet and the location in the axial direction of the magnetic detection element.

7. The rotation angle detection device according to claim 1, wherein a distance in the axial direction between the location in the axial direction of the shield and the location in the axial direction of the magnetic detection element is shorter than a distance in the axial direction between the location in the axial direction of the shield and the location in the axial direction of the wire member.

8. The rotation angle detection device according to claim 1, wherein a width in the axial direction of the shield is smaller than a width in a radial direction of the shield.

9. The rotation angle detection device according to claim 1, wherein
a shape of the shield is similar to a shape of the wire member around the shaft as seen in the axial direction, and
the shield and the wire member overlap with each other as seen in the axial direction.

10. The rotation angle detection device according to claim 1, wherein the shield has an annular shape extending in a circumferential direction.

11. The rotation angle detection device according to claim 1, wherein an end portion on a radially inner side of the shield is bent toward another side in the axial direction.

12. The rotation angle detection device according to claim 1, wherein
the magnet has N (representing an even number that is two or more) magnetic poles on the one side in the axial direction and has N magnetic poles on another side in the axial direction,
the N magnetic poles on the one side in the axial direction and the N magnetic poles on the other side in the axial direction are disposed at locations that coincide with each other in a circumferential direction,
two of the magnetic poles that are adjacent in the axial direction are different from each other, and
two of the magnetic poles that are adjacent in the circumferential direction are different from each other.

13. The rotation angle detection device according to claim 12, further comprising
a holder fixed to an end portion on the one side in the axial direction of the shaft and holding the magnet, wherein
the holder has a circumferential wall covering a radially outer side of the magnet and formed from a magnetic material.

14. The rotation angle detection device according to claim 1, wherein the magnetic detection element is a magnetoresistive effect element having a magnetic detection direction perpendicular to the axial direction.

15. The rotation angle detection device according to claim 1, further comprising
a support member fixing another side in the axial direction of the shield and the one side in the axial direction of the wire member to each other, wherein
the support member is formed from an insulation material, and
the shield and the wire member are electrically insulated from each other.

16. The rotation angle detection device according to claim 15, wherein the shield has a cut into which a fitting portion provided to the support member is fitted.

17. The rotation angle detection device according to claim 15, wherein
the shield has a through hole penetrating therethrough in the axial direction, and
the support member is provided at: a portion within the through hole; and a portion on the one side in the axial direction of the through hole and the shield around the through hole.

18. The rotation angle detection device according to claim 1, further comprising
a holder fixed to an end portion on the one side in the axial direction of the shaft and holding the magnet, wherein
the holder has a tubular circumferential wall covering a radially outer side of the magnet with a gap interposed therebetween, and
the gap between the radially outer side of the magnet and the circumferential wall is filled with a fixation member.

19. A rotary electric machine comprising:
the rotation angle detection device according to claim 1;
the shaft;
the wire member;
a rotor configured to rotate integrally with the shaft and having a field winding and a field core around which the field winding is wound;
a stator disposed radially outward of the rotor and having a stator core around which an armature winding is wound; and
a bracket covering an outer side of each of the rotor and the stator and holding one end side and another end side of the shaft via bearings.
